(19) United States
(12) Patent Application Publication
(10) Pub. No.: US 2013/0247993 A1
(43) Pub. Date: Sep. 26, 2013

(54) Enhanced Efficiency Polymer Solar Cells Using Aligned Magnetic Nanoparticles

(71) Applicant: XIONG GONG, Hudson, OH (US)

(72) Inventor: XIONG GONG, Hudson, OH (US)

(21) Appl. No.: 13/850,195

(22) Filed: Mar. 25, 2013

Related U.S. Application Data
(60) Provisional application No. 61/614,741, filed on Mar. 23, 2012.

(51) Int. Cl. H01L 51/42

(52) U.S. Cl. CPC H01L 51/426; Y10S 977/735; Y10S 977/811; Y10S 977/838; Y10S 977/948; B82Y 30/00
USPC 136/263; 438/82; 977/735; 977/811; 977/838; 977/948

(57) ABSTRACT

Polymer solar cells with enhanced efficiency utilize an active layer formed of a composite of polymer/fullerene and Fe₃O₄ nanoparticles. During the formation of the solar cell, the composite mixture is subjected to an external magnetic field that causes the nanoparticles to align their magnetic dipole moments along the direction of the magnetic field, so as to form a plurality of Fe₃O₄ nanochains. These nanochains serve to adjust the morphology and phase separation of the polymer/fullerene, and also serve to induce an internal electrical field by spin-polarization of the nanochains serve to increase the charge separation and charge transport processes in the solar cell, enhancing the short-current density (J_{sc}) and ultimately, the photoelectric converted efficiency (PCE) of the solar cell.

### CROSS-REFERENCE TO RELATED APPLICATION

This application claims the benefit of U.S. Provisional Patent Application No. 61/614,741, filed on Mar. 23, 2012, the contents of which are incorporated herein by reference.

### TECHNICAL FIELD

Generally, the preset invention relates to polymer solar cells. In particular, the present invention relates to polymer solar cells using aligned magnetic nanochains. More particularly, the present invention relates to polymer solar cells using aligned Fe₃O₄ nanochains that are induced by the self-assembly of Fe₃O₄ nanoparticles in the presence of an applied magnetostatic field to increase the photoelectric conversion efficiency of the solar cell.

### BACKGROUND ART

Polymer solar cells (PSCs) hold the promise for a cost-effective, lightweight solar energy conversion platform, which offers significant benefits over inorganic silicon solar cells. New material combinations and solar cell designs have been developed to realize bulk heterojunction (BHJ) solar cells with increased energy conversion efficiency. Specifically, such efforts are focused on the improvement of three operating parameters that determine the conversion efficiency of the polymer solar cell, including: the open-circuit voltage (V_{oc}), the short-circuit current density (J_{sc}), and the fill factor (FF), which represents the curvature of the current density-voltage characteristic. To date, polymer solar cells (PSC) have achieved energy conversion efficiencies of approximately 7-8% by reducing both the optical band gap and the highest occupied molecular orbital (HOMO) of the semiconducting polymers forming the solar cell, and by optimizing the morphology of the polymer/fullerene blended film of the active layer of the polymer solar cell with thermal and solvent annealing. While the open-circuit voltage (V_{oc}) and the fill factor (FF) parameters of polymer solar cells have almost reached a level equal to that of inorganic silicon solar cells, the performance of polymer solar cells is still lower, as compared to inorganic solar cells, due to the performance gap in short circuit current density (J_{sc}) that exists between inorganic and polymer solar cells (PSCs). Moreover, because charge carriers in a polymer solar cell (PSC) are subject to interfacial recombination along the entire internal collection pathway, charge transport through an organic polymer solar cell is typically several orders of magnitude slower than in an inorganic solar cell. This interfacial recombination is caused by the formation of a mobile excited state or excitons that are produced by organic materials when they absorb light, which is in contrast to free electron-hole (e-h) pairs, which are produced in inorganic solar cells.

Thus, the fundamental physical processes exhibited by organic and inorganic solar cells are completely different. For example, the fundamental physical processes in an organic BHJ solar cell device are as follows: photons from sunlight are absorbed inside a solar cell and excite a donor, leading to the creation of excitons in the conjugated polymer active layer of the solar cell. The created excitons begin to diffuse within the donor phase, and if they encounter the interface with an acceptor, a fast dissociation takes place, which leads to a charge separation. The resulting metastable electron-hole pairs formed across the donor/acceptor (D/A) interface are coulombically bound, and an electric field is needed to separate them into free charges. Therefore, under typical operating conditions, the photon-to-free-electron conversion efficiency of polymer solar cells is not maximized. Subsequently, the separated free electrons (holes) are transported, with the aid of the internal electric field formed by the use of electrodes with different work functions, towards the cathode (anode) where they are collected by the electrodes and driven into the external circuit. However, the excitons can decay, resulting in luminescence, if they are generated too far from the donor/acceptance (D/A) interface. Thus, the excitons should be formed within the diffusion length of the interface as an upper limit for the size of the conjugated polymer phase in the organic BHJ solar cell.

As such, there are several primary causes of limited energy conversion efficiency in organic photovoltaic (OPV) devices, such as polymer BHJ-based solar cells, including: energy level misalignment; insufficient light trapping and absorption; low exciton diffusion lengths; non-radiative recombination of charges or charge-transfer excitons (CTEs), which include electrons at the acceptor and holes at the donor that are bound by Coulomb attraction; and low carrier mobilities. In the most efficient polymer-fullerene organic photovoltaic devices, 50% or more of the energy loss is caused by the recombination of charge-transfer excitons.

Therefore, there is a need for an organic polymer solar cell that achieves greater short-circuit current density (J_{sc}) by utilizing aligned magnetic nanochains, such as Fe₃O₄ nanochains (NC), that are induced by the self-assembly of magnetic nanoparticles, such as Fe₃O₄ nanoparticles (NP), in the presence of an applied vertically magnetostatic field. In addition, there is a need for an organic polymer solar cell that has increased photoelectric converted efficiency (PCE).

### SUMMARY OF THE INVENTION

In light of the foregoing, it is a first aspect of the present invention to provide a solar cell comprising an at least partially light transparent electrode; an active layer disposed upon the at least partially light transparent electrode, the active layer formed of a composite of at least one conjugated polymer as an electron donor, at least one fullerene as an electron acceptor, and Fe₃O₄ nanochains formed of Fe₃O₄ nanoparticles aligned along their magnetic dipole moments; and a second electrode disposed upon the active layer.

It is another aspect of the present invention to provide a method of forming a solar cell comprising providing an at least partially transparent electrode; providing a mixture of at least one polymer as an electron donor, at least one fullerene as an electron acceptor, and Fe₃O₄ nanoparticles; disposing said mixture upon the at least partially transparent electrode to form an active layer; exposing the mixture to a magnetic field, such that Fe₃O₄ nanochains are formed from the Fe₃O₄ nanoparticles, and are aligned along their magnetic dipole moments; and disposing a second electrode upon the active layer.

In another aspect of the present invention a solar cell includes an at least partially light transparent electrode; an active layer disposed upon said at least partially transparent electrode, said active layer formed of a composite of at least one electron donor, at least one electron acceptor, and magnetic nanoparticles aligned along their magnetic dipole moments; and a second electrode disposed upon said active layer.

In yet another aspect of the present invention, a method of forming a solar cell includes providing an at least partially light transparent electrode; providing a mixture of at least one polymer, at least one fullerene, and magnetic nanoparticles; disposing said mixture upon said at least partially light transparent substrate to form an active layer; exposing said mixture to a magnetic field, such that said magnetic nanoparticles are aligned along their magnetic dipole moments; and disposing a second electrode upon said active layer.

### BRIEF DESCRIPTION OF THE DRAWINGS

These and other features and advantages of the present invention will become better understood with regard to the following description, appended claims, and accompanying drawings wherein:

FIG. 1 is a schematic view of a polymer solar cell in accordance with the concepts of the present invention;

FIG. 2 is a schematic view of a polymer/fullerene composite material used in combination with aligned Fe₃O₄ nanochains used to form an active layer of the polymer solar cell in accordance with the concepts of the present invention;

FIG. 3 is a diagrammatic view showing an external magnetic field aligned Fe₃O₄ nanochains induced in the polymer solar cell by polarizing the Fe₃O₄ nanoparticles in accordance with the concepts of the present invention;

FIG. 3A is a diagrammatic view showing the aligned magnetic nanoparticles forming channels in the polymer/fullerene composite of the active layer of the solar cell when exposed to a magnetic field in accordance with the concepts of the present invention;

FIG. 4A is a diagrammatic view of a TEM (transmission electron microscopy) image of an active layer formed of pristine P3HT:PC61BM in accordance with the concepts of the present invention;

FIG. 4B is a diagrammatic view of a TEM (transmission electron microscopy) image of an active layer formed of P3HT:PC61BM+Fe₃O₄ in accordance with the concepts of the present invention;

FIG. 4C is a diagrammatic view of a TEM (transmission electron microscopy) image of an active layer formed of P3HT:PC61BM nanochains aligned by an external magnetic field in accordance with the concepts of the present invention;

FIG. 5A is a graph showing the J-V curves of polymer solar cells using an active layer of pristine PTB7-F20:PC71BM, an active layer of PTB7-F20:PC71+Fe₃O₄ without external magnetic field alignment treatment, and an active layer of PTB7-F20:PC71BM+Fe₃O₄ with external magnetic field alignment treatment under illuminated conditions in accordance with the concepts of the present invention;

FIG. 5B is a graph showing the J-V curves of polymer solar cells using an active layer of pristine PTB7-F20:PC71BM, an active layer of PTB7-F20:PC71+Fe₃O₄ without external magnetic field alignment treatment, and an active layer of PTB7-F20:PC71BM+Fe₃O₄ with external magnetic field alignment treatment under dark conditions in accordance with the concepts of the present invention;

FIG. 6A is a graph showing the J-V curves of polymer solar cells using an active layer of pristine P3HT:PC61BM, an active layer of P3HT:PC61BM+Fe₃O₄ without external magnetic field alignment treatment, and an active layer of P3HT:PC61BM+Fe₃O₄ with external magnetic field alignment treatment under illuminated conditions in accordance with the concepts of the present invention;

FIG. 6B is a graph showing the J-V curves of polymer solar cells using an active layer of pristine P3HT:PC61BM, an active layer of P3HT:PC61BM+Fe₃O₄ without external magnetic field alignment treatment, and an active layer of P3HT:PC61BM+Fe₃O₄ with external magnetic field alignment treatment under illuminated conditions in accordance with the concepts of the present invention;

FIG. 7A is a graph showing the EQE (external quantum efficiency) of polymer solar cells using an active layer of pristine PTB7-F20:PC71BM, an active layer of PTB7-F20:PC71+Fe₃O₄ without external magnetic field alignment treatment, and an active layer of PTB7-F20:PC71BM+Fe₃O₄ with external magnetic field alignment treatment in accordance with the concepts of the present invention;

FIG. 7B is a graph showing the absorption of polymer solar cells using an active layer of pristine PTB7-F20:PC71BM, an active layer of PTB7-F20:PC71+Fe₃O₄ without external magnetic field alignment treatment, and an active layer of PTB7-F20:PC71BM+Fe₃O₄ with external magnetic field alignment treatment in accordance with the concepts of the present invention;

FIGS. 8A-F are diagrammatic views of AFM (atomic force microscopy) images of films cast from pristine P3HT:PC61BM (A), P3HT:PC61BM blended with Fe₃O₄ nanoparticles without magnetic field induced alignment of Fe₃O₄ nanoparticles (B), and P3HT:PC61BM blended with Fe₃O₄ nanoparticles with magnetic field induced alignment of Fe₃O₄ nanoparticles (C) in accordance with the concepts of the present invention;

FIGS. 9A-C are diagrammatic views of TEM images of the active layers of pristine PTB7-F20:PC71BM (A), an active layer of PTB7-F20:PC71+Fe₃O₄ without external magnetic field alignment treatment (B), and an active layer of PTB7-F20:PC71BM+Fe₃O₄ with external magnetic field alignment treatment (C) in accordance with the concepts of the present invention;

FIGS. 10A-F are diagrammatic views of AFM (atomic force microscopy) images and phase images of films cast from an active layer of pristine PTB7-F20:PC71BM (A), an active layer of PTB7-F20:PC71+Fe₃O₄ without external magnetic field alignment treatment (B), and an active layer of PTB7-F20:PC71BM+Fe₃O₄ with external magnetic field alignment treatment (C) in accordance with the concepts of the present invention;

FIGS. 11A-D are graphs showing the effect of the Fe₃O₄ nanoparticles without and with magnetic field alignment treatment on charge transport properties in accordance with the concepts of the present invention; and

FIGS. 12A-F are diagrammatic views of TEM (transmission electron microscopy) images of pristine P3HT:PC61BM (A-B), of P3HT:PC61BM blended with Fe₃O₄ nanoparticles without external magnetic field alignment treatment (C-D), and P3HT:PC61BM blended with Fe₃O₄ nanoparticles with magnetic field induced alignment treatment (E-F) in accordance with the concepts of the present invention.

### DETAILED DESCRIPTION OF THE INVENTION

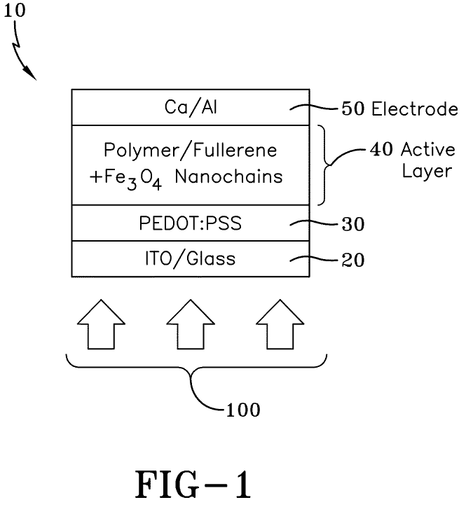

A polymer solar cell in accordance with the concepts of the present invention is generally referred to by numeral 10, as shown in FIG. 1 of the drawings. The polymer solar cell 10 includes an indium-tin-oxide (ITO) substrate or electrode 20 upon which a PEDOT:PSS buffer layer 30 is disposed. Alternatively, the electrode 20 may comprise any suitable high-work function metal, such as Al or Ag, or such metal may be combined with ITO, for example. Disposed upon the PEDOT:PSS layer 30 is an active layer 40 formed of a composite of polymer/fullerene and Fe₃O₄ nanoparticles. Finally, disposed upon the active layer 40 is a calcium and aluminum electrode layer 50, however the electrode layer 50 may be formed of any suitable low work-function metal. Thus, during operation, the ITO layer 20, which is at least partially transparent to light, is configured to receive light 100 from any suitable source of solar energy, such as the sun.

The polymer solar cell is fabricated, such that the ITO layer 20 is formed as a glass coated substrate that was cleaned with detergent, then ultrasonicated in deionized water, acetone, and isopropanol, and then subsequently dried in an oven overnight. The ITO glass 20 is then treated with oxygen plasma for 40 minutes to reform the surface of the ITO layer 20. Poly(ethylenedioxythiophene), or PEDOT, was doped with poly(styrenesulfonate), or PSS, to form PEDOT:PSS (Baytron P) and was spin-cast, so as to form the buffer layer 30 that is disposed upon the ITO layer 20 at a thickness of approximately 40 nm. The ITO layer 20 and the PEDOT:PSS buffer layer 30 disposed thereon was then preheated on a digitally controlled hotplate at 150 degrees C. for 10 minutes.

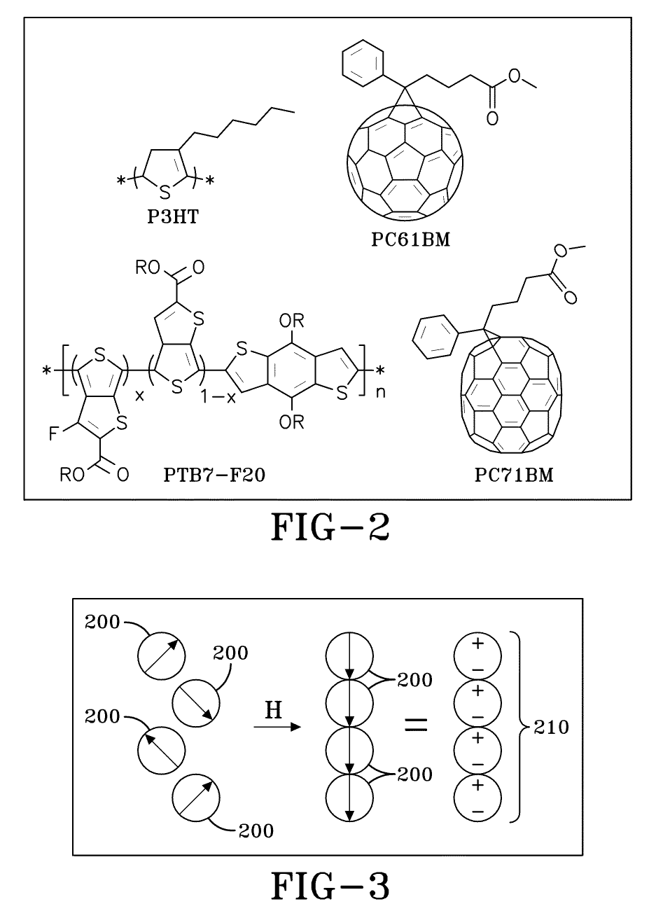

The active layer 40 of the solar cell 10 is formed as a composite of a combination of at least one conjugated polymer or p-type organic molecules, at least one fullerene (or fullerene derivative) or n-type organic molecules, and magnetic nanochains or nanoparticles of metal or metal oxide, such as CoO, NiO, Co, Ni, and Fe₃O₄ for example. However, the following discussion relates to the use of Fe₃O₄ in forming the active layer 40 of the solar cell 10, however, it is contemplated that any suitable metal or metal oxide may be used. It should be appreciated that the at least one conjugated polymer of the solar cell 10 serves as an electron donor, and the at least one fullerene serves as an electron acceptor. For example, the polymer/fullerene combination may comprise either of: P3HT:PC61BM or PTB7-F20:PC71BM, as shown in FIG. 2, although any other suitable combination may be used. It should be appreciated that the conjugated polymer may comprise any suitable polymer, such as poly(3-hexylthiophene) (P3HT) and thieno[3,4-b]thiophene benzodithiophene (PTB7-F20) for example, while the fullerene may comprise any suitable fullerene, such as phenyl-C61-butyric acid methyl ester (PC61BM) and phenyl-C71-butyric acid methyl ester (PC71BM) for example. In another aspect, it should be appreciated that the conjugated polymer comprises an electron donor and the fullerene (or fullerene derivative) comprises an electron acceptor. It should also be appreciated that the solar cell 10, including active layer 40, may be solution processed, such as by spin-casting, dip-casting, drop casting, and may include printing technology, such as spray-coating, dip-coating, doctor-blade coating, slot coating, dispensing ink jet printing, thermal transfer printing, silk-screen printing, offset printing, gravure printing, and flexo printing for example.

It should be further appreciated that the active layer may be formed of a bulk heterojunction that is a composite of an electron donor and an electron acceptor, with the bulk heterojunction composite including the electron donor, electron acceptor, and functionalized inorganic nanoparticles and/or quantum dots, such as those functionalized by a magnetic field as discussed herein. In one aspect, the functionalized inorganic nanoparticles and/or quantum dots may comprise electronic conductive nanoparticles and magnetic nanoparticles that are functionalized by an external magnetic or electric field.

Continuing, with regard to the fabrication of the solar cell 10 having a P3HT:PC61BM based polymer/fullerene active layer 40, a donor/acceptor blend ratio of 1:0.8 and a solution concentration of 1 wt %, 100 uL were used and dissolved in ortho-dichlorobenzene (ODCB) by stirring the mixture at room temperature in a glove box, while Fe₃O₄ nanoparticles (NPs) (5 mg/mL, 1 uL) were added into the mixture at a weight ratio of 0.5 wt %. It should be appreciated that the Fe₃O₄ nanoparticles have a size of approximately 5 nm, and are capped by surfactant oleic acid (OA) (Sigma Aldrich). Next, the P3HT/PC61BM/Fe₃O₄ mixture was subjected to ultrasonic processing and stirring for six hours to disperse the Fe₃O₄ nanoparticles into the polymer/fullerene solution mixture. Next, the P3HT:PC61BM+Fe₃O₄ mixture was dispersed on the ITO (including PEDOT:PSS layer 30) substrate 20 and alignment treated by a magnetic field produced by square magnets (Amazing Magnets Co. C750, Licensed NdFeB) for about two minutes. The direction of the magnetic field produced by the magnets was perpendicular and substantially vertical to the ITO layer 20 and P3HT:PC61BM+Fe₃O₄ carried thereon, such that one magnet had its magnetic north (N) pole positioned proximate to the top of the active layer 40, while the other magnet had its magnetic south (S) pole positioned proximate to the bottom of the ITO layer 20. Furthermore, the distances between the two magnets and the ITO layer 20 therebetween were maintained at approximately 5 cm. After the magnetic alignment treatment, the ITO was spin-cast at 800 RPM (revolutions per minute) for 20 seconds, whereupon the magnetic field was again introduced to the active layer 40 with the same distance and direction as previously discussed. The application of this magnetic field was continued until the P3HT:PC61BM/Fe₃O₄ layer 40 was dried, after approximately three minutes. Finally, after the active layer 40 was dried, solar cell 10 was then transferred to a vacuum chamber (4×10⁻⁶ mbar), whereupon the electrode layer 50, formed of calcium (Ca) of approximately 5 nm and aluminum (Al) of approximately 100 nm, was disposed upon the active layer 40. The solar cell 10 was not thermally annealed.

Alternatively, the PTB7-F20:PC71BM based active layer 40 was fabricated using a blend ratio of 1:1.5, 1 wt %, 100 uL that was dissolved in a mixed solvent of ortho-dichlorobenzene (ODCB) 1,8-diiodooctane (DIO) (97%:3% by volume) by stirring at room temperature in a glove box. It should be appreciated that adding about 3% DIO (1,8-diiodooctane (DIO)/ODCB, v/v) to the combination allows better photovoltaic results to be achieved for the solar cell 10 using the PTB7-F20:PC71BM active layer 40. Fe₃O₄ nanoparticles (5 mg/mL, 1 uL) were added to the blended mixture at a weight ratio of 0.5 wt %, followed by ultrasonic processing and stirring for six hours, so as to disperse the Fe₃O₄ nanoparticles into the mixture of the PTB7-F20:PC71BM polymer/fullerene. Next, the P3HT:PC61BM+Fe₃O₄ mixture was dispersed on the ITO substrate 20 (including PEDOT:PSS layer 30) and alignment treated by a magnetic field produced by square magnets (Amazing Magnets Co. C750, Licensed NdFeB) for about two minutes. The direction of the magnetic field produced by the magnets was perpendicular and substantially vertical to the ITO layer 20 and P3HT:PC61BM+Fe₃O₄ layer 40 carried thereon, such that one magnet had its magnetic north (N) pole positioned proximate to the top of the active layer 40, while the other magnet had its magnetic south (S) pole positioned proximate to the bottom of the ITO layer 20. Furthermore, the distances between the two magnets and the ITO layer 20 therebetween were maintained at approximately 10 cm. After the magnetic alignment treatment, the ITO was spin-cast at 1000 RPM (revolutions per minute) for 15 seconds, whereupon the magnetic field was again introduced to the active layer 40 with the same distance and direction as previously discussed. The application of this magnetic field was continued until the PTB7-F20:PC71BM/Fe₃O₄ active layer 40 was dried, after approximately three minutes. Thus, after the active layer 40 was dried, the solar cell 10 was then transferred to a vacuum chamber (4×10⁻⁶ mbar), whereupon the electrode layer 50, formed of calcium (Ca) of approximately 5 nm and aluminum (Al) of approximately 100 nm, was disposed upon the active layer 40. The solar cell 10 was not thermally annealed.

To understand how the operation of the fabricated solar cells 10 operate to achieve an increase in short-circuit current density (J_{sc}), it is necessary to identify not only which factors affect the short-circuit current (I_{sc}), but also how the Fe₃O₄-aligned nanochains affect the transport of charge carriers when blended into the polymer/fullerene composite of the active layer 40. In particular, limiting the loss of photogenerated charge carriers during their transport can improve the performance of bulk heterojunction (BHJ) solar cells, such as the solar cell 10. Short-circuit current I_{sc} is determined by the product of the photoinduced charge carried density, if loss-free contacts are used, with the charge carrier mobility within the organic semiconductors, where I_{sc}=neμE (1) where n is the density of charge carriers; e is the elementary charge, u is the charge mobility, and E is the electric field. Assuming 100% efficiency of the photoinduced charge generation in a BHJ solar cell device, n is the number of absorbed photons per unit volume.

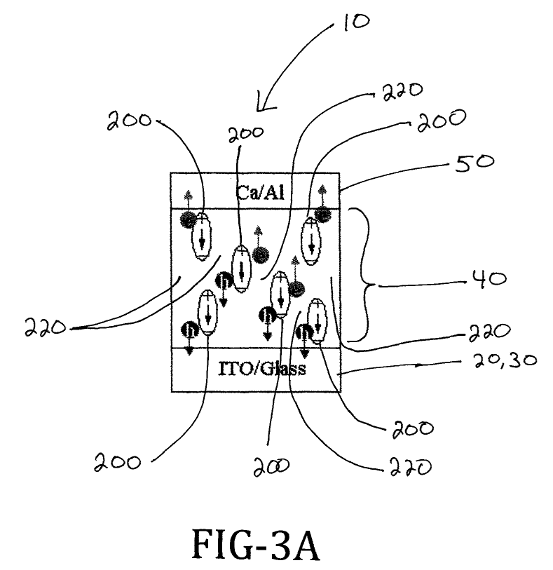

Traditionally, magnetostatic fields have often been used to direct the assembly of nanoparticles (NPs), generally resulting in the formation of wire or chain-like structures. Under a magnetic field, the Fe₃O₄ nanoparticles, or other suitable magnetic nanoparticles, align their magnetic dipole moments along the direction of the externally applied magnetic field (H), forming linear chains, or nanochains 210, in a colloidal solution, as shown in FIG. 3. However, it should be appreciated that the magnetic alignment process may not form a chain of nanoparticles, but may align magnetic dipole moments of the magnetic nanoparticles of the active layer 40, so as to form temporary channels 220 between the electrodes 20 and 50, as shown in FIG. 3A, for transporting separated charge carriers (holes/electrons) to the corresponding electrodes 20,50. As a result, the mobilities of the charge carriers (holes/electrons) in the polymer/fullerene is enhanced, and reduced charge carrier recombination, increased Jsc and FF are achieved. The magnetic force of a magnetic nanoparticle under a static magnetic field can be expressed by:

$$F = \frac{V {Δ}_{χ}}{{μ}_{o} ( B ∇ ) B} \qquad ( 2 )$$

where V is the volume of the particle, Δχ is the difference in the magnetic susceptibilities of the particle, μₒ is the vacuum permeability, and B is the magnetic field strength, and Δ is the field gradient. Specifically, the external magnetic field exerts a torque on the magnetic dipole moments of the Fe₃O₄ particles, forcing them to align with the magnetic field. The interparticle magnetic dipole-dipole couplings and the external coupling of the magnetic dipoles to the magnetic field of the Fe₃O₄ favor linear chain growth along the magnetic-field flux lines. If a magnetic body of infinite size is magnetized, free magnetic dipoles are induced on both its ends. This gives rise to a magnetic field in the opposite direction to the magnetization, which is called the demagnetizing field, H_{d}. It is given by:

$${H}_{d} = \frac{NM}{{μ}_{0}} \qquad ( 3 )$$

where μₒ, M, and N are the permeability of a vacuum, the magnetization, and the demagnetization factor (dimensionless quantity), respectively. The demagnetizing factor, N, depends on the shape of the sample, for example, for spheres, N is equal to ⅓. This mechanism of magnetic dipolar interaction, or dipolar coupling, refers to the direct interaction between two magnetic dipoles. The strength of dipolar interactions is relative to the individual particle anisotropy energy Eₐ arising either from bulk crystalline anisotropy ˜KV, where K is anisotropy constant, and V, which is the particle volume or particle's shape and surface anisotropy. The Fe₃O₄ nanoparticles formed head-to-tail structures to minimize the systematic energy. Based on the above derivation, dipoles of concentration n create the average electric field,

$$E = \frac{4 π}{ɛ} pn = \frac{4 π}{ɛ} σ f = {E}_{max} f \qquad ( 4 )$$

where ε is the dielectric permittivity of a matrix, the dipole moment p=σlA=σΩ, such that A, l, and Ω are, respectively, the particle face area, particle length, and particle volume. It should be appreciated that f is the dimensionless volume fraction occupied by the dipole particles, and Eₘₐₓ is the electric field strength for a hypothetical uniform polarization with f=1. The energy of a single field-aligned dipole is

$$w = - p \cdot E = - \frac{4 {πσ}^{2} Ω}{ɛ} f . \qquad ( 5 )$$

The desired strong polarization takes place when |w|>>kT (₆) where k is the Boltzmann constant and T is the temperature. Such a strong inequality |w|>>kT shows that there exists a broad range of parameters for which the system is polarized. The strong interdipole interaction

$$\frac{\vert w \vert}{k} ≡ T$$

makes the system capable of spontaneous polarization. Based on the foregoing, it can be inferred that the superparamagnetism of aligned Fe₃O₄ nanochains produce an internal electrical field through dipolar-dipolar interaction and spin-polarization, which both increase the charge separation efficiency in the solar cell 10 and ensure high mobility charge carrier transport with reduced bimolecular recombination in the solar cell 10 by applying a strong electric field to draw the electrons and holes apart.

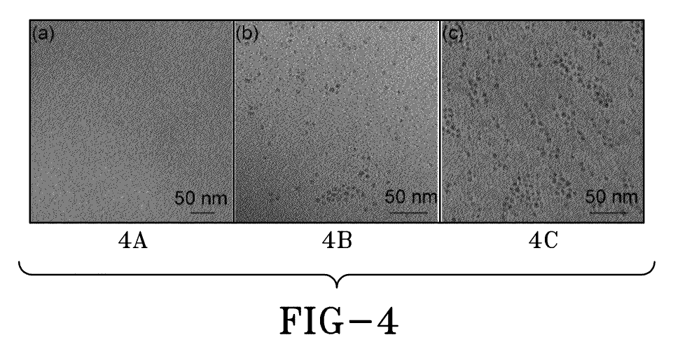

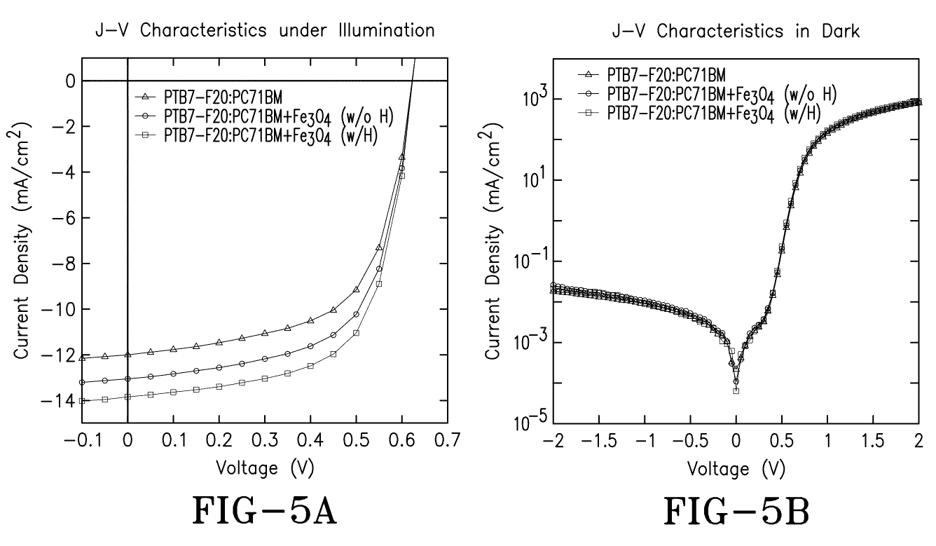

The solar cell 10 of the present invention incorporates external magnetic field aligned Fe₃O₄ nanochains into the polymer/fullerene based BHJ photovoltaic active layer 40 to increase the efficiency of the solar cell 10 that is enhanced by the induced polarization provided by the electric field of the Fe₃O₄ nanostructures. Thus, it should be appreciated that under the influence of an external magnetic field, Fe₃O₄ nanoparticles 200 of the active layer 40 align their magnetic dipole moments along the direction of the external magnetic field (H), forming linear nanochains 210 in the polymer/fullerene composites, as shown in FIG. 3. However, as previously discussed, it should be appreciated that the magnetic alignment process may not form a chain of nanoparticles 200, but may align magnetic dipole moments of the magnetic nanoparticles of the active layer 40, so as to form temporary channels 220 between the electrodes 20 and 50, as shown in FIG. 3A, for transporting separated charge carriers (holes/electrons) to the corresponding electrodes 20,50. As a result, the mobilities of the charge carriers (holes/electrons) in the polymer/fullerene is enhanced, and reduced charge carrier recombination, increased Jsc and FF are achieved. In the present invention, a 30-degree tilted TEM (transmission electron microscope) was used to characterize the distribution and assembly of the Fe₃O₄ nanoparticles in the P3HT:PC61BM based BHJ active layer 40, the diameter of oleic acid capped Fe₃O₄ nanoparticles (dispersed in toluene) was about 5 nm, and they were polydispersed. Compared with pristine P3HT:PC61BM, shown in FIG. 4A, and P3HTPC61BM+Fe₃O₄, shown in FIG. 4B, based devices, very short chains of five to ten Fe₃O₄ nanoparticles are found after induced alignment by the vertically applied magnetostatic field, as shown in FIG. 4C. This reveals that massive aggregation of nanoparticles does not occur, and only magnetic dipolar interaction plays a role in the formation of short chains. It should be noted that formation of the very short Fe₃O₄ chains is due to the strong repulsion of oleic acid molecules and the resistance from the polymer/fullerene matrix, which prevents the formation of long chains. Thus, for oleic acid capped Fe₃O₄ nanoparticles, fibrous assembly is not observed, which reveals that massive aggregation of nanoparticles does not occur and that only magnetic dipolar interaction plays a role in the formation of very short nanochains. Noticing that the former are electrostatically stabilized while the latter is sterically stabilized, it is inferred that the assembly is not only induced by magnetic dipolar effects, but also depends on the electrostatic interactions. Chemical functionalization of Fe₃O₄ nanoparticles, such as ligand exchange and surface chemistry of Fe₃O₄, also assist to optimize the alignment of Fe₃O₄ nanoparticles under a magnetic field.

In order to determine the influence of magnetic field aligned Fe₃O₄ nanoparticles in the polymer solar cell 10 of the present invention, solar cells 10 formed from pristine polymer/fullerene (P3HT:PC61BM and PTB7-F20:PC71BM) and polymer/fullerene+Fe₃O₄ nanoparticles (P3HT:PC61BM+Fe₃O₄ and PTB7-F20:PC71BM+Fe₃O₄) without the magnetic field treatment were fabricated as a control group. Furthermore, all devices were not heat annealed using pervious-annealing or post-annealing. The photovoltaic results of these two types (P3HT:PC61BM and PTB7-F20:PC71BM) of solar cells 10 are listed in Table 1 below. Specifically, Table 1 shows the photovoltaic performances of pristine polymer/fullerene (P3HT:PC61BM and PTB7-F20:PC71BM), and Fe₃O₄ nanoparticles blended polymer/fullerene (P3HT:PC61BM and PTB7-F20:PC71BM), with and without magnetic field (H) alignment.

TABLE 1

| Polymer Solar Cell | | J_{sc} | | PCE | Rs^{a} |
|---|---|---|---|---|---|
| (PSC) | V_{oc} (V) | (mA/cm²) | FF (%) | (%) | (Ω/cm²) |
| P3HT:PC61BM | 0.60 | 7.81 | 63.50 | 2.98 | 8.20 |
| P3HT:PC61BM + Fe₃O₄ | 0.60 | 8.39 | 65.20 | 3.28 | 6.65 |
| (w/o H) | | | | | |
| P3HT:PC61BM + Fe₃O₄ | 0.60 | 8.97 | 68.30 | 3.67 | 5.50 |
| (w/H) | | | | | |
| PTB7-F20:PC71BM | 0.63 | 12.01 | 63.60 | 4.81 | 6.46 |
| PTB7- | 0.63 | 13.06 | 65.30 | 5.38 | 5.82 |
| F20:PC71BM + Fe₃O₄ | | | | | |
| (w/o H) | | | | | |
| PTB7- | 0.63 | 13.86 | 66.40 | 5.80 | 5.60 |
| F20:PC71BM + Fe₃O₄ | | | | | |
| (w/H) | | | | | |

^{a}Series resistance deduced from the inverse slope near J_{sc} and V_{oc} in the J-V curve under illumination.

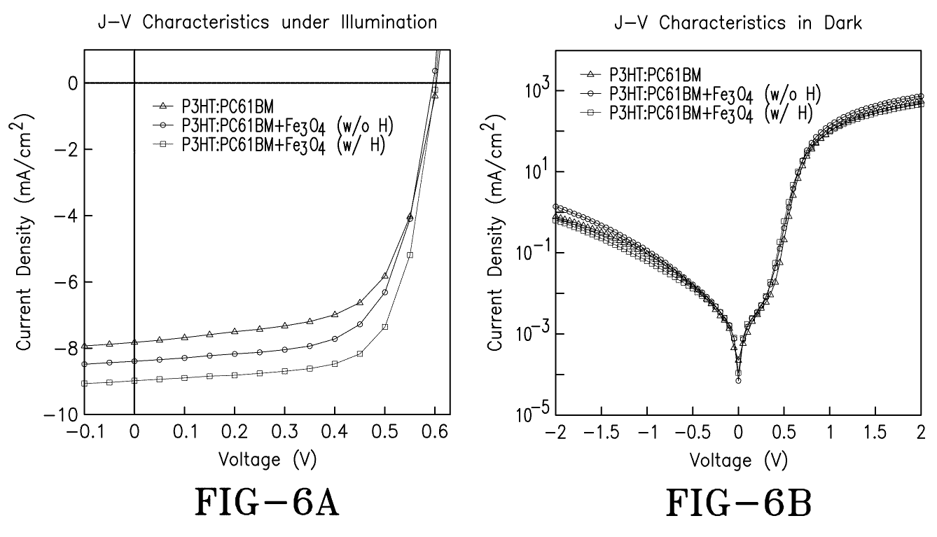

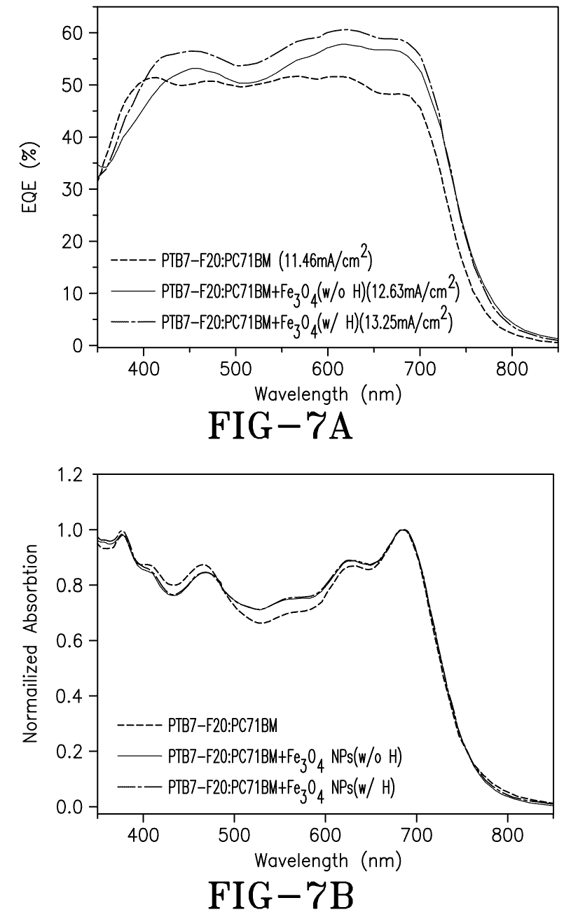

In addition, the corresponding J-V curves of a pristine PTB7-F20:PC71BM based solar cell 10, a PTB7-F20:PC71BM based solar cell 10 without magnetic field (H) treatment, and a PTB7-F20:PC71BM based solar cell 10 with magnetic field (H) treatment under illuminated conditions, is shown in FIG. 5A, and under dark conditions, is shown in FIG. 5B. In addition, the corresponding J-V curves of a pristine P3HT:PC61BM based solar cell 10, a P3HT:PC61BM based solar cell 10 without magnetic field (H) treatment, and a P3HT:PC61BM based solar cell 10 with magnetic field (H) treatment under illuminated conditions is shown in FIG. 6A and under dark conditions is shown in FIG. 6B.

In the first control experiment, a solar cell with an active layer formed of pristine P3HT:PC61BM and PTB7-F20:PC71BM attained a performance level that reached a normal level. For example, the open-circuit voltage (V_{oc}), short-circuit density (J_{sc}), and fill factor (FF) of the P3HT:PC61BM based solar cell are respectively, 0.6V, 7.81 mA/cm², and 0.64, while the power conversion efficiency (PCE) reached 2.98%.

The second control groups of solar cells having an active layer formed by polymer/fullerene+Fe₃O₄ nanoparticles without the external magnetic field aligned treatment, led to a small increase in J_{sc}, as compared with the pristine polymer/fullerene based control devices. The likely reason for this is that the magnetic field originated from the superparamagnetism of Fe₃O₄ nanoparticles, resulting in the increase of the population of triplet excitons. Furthermore, considering that efficient energy transduction requires separation of photogenerated electron-hole pairs into long-lived dissociated charges with a high quantum yield and minimal loss of free energy. A potential concern of this charge-separation process is that the electron and hole must overcome their mutual Coulomb attraction,

$$V = \frac{{e}^{2}}{4 {πɛ}_{r} {ɛ}_{0} r} \qquad ( 7 )$$

where e is the charge of an electron, εᵣ is the dielectric constant of the surrounding medium, εₒ is the permittivity of a vacuum, and r is the electron hole separation distance. Considering the increasing of εᵣ after blending Fe₃O₄ nanoparticles into the polymer/fullerene system, Coulomb attraction of the electron and hole will be decreased, thus increasing the efficiency of photogenerated electron-hole pairs into long-lived dissociated charges.

Next, solar cells 10 having active layer 40 formed of polymer/fullerene and Fe₃O₄ nanoparticles (P3HT:PC61BM+Fe₃O₄ and PTB7-F20:PC71BM+Fe₃O₄) were treated by an external magnetic field in which the magnetic field direction was vertical to the active layer 10, as previously discussed. The P3HT/PC61BM active layer 40 with aligned Fe₃O₄ nanochains attained a photo conversion efficiency of (PCE) 5.80% (V_{oc}=0.63 V, J_{sc}=13.86 mA/cm², and FF=0.66). The V_{oc} in these two types of polymer/fullerene based systems have not been affected by Fe₃O₄ nanoparticles without and with the external magnetic field treatment. In actuality, the V_{oc} will be decreased when the concentration of Fe₃O₄ nanoparticles is too high, and the optimum ratio of 0.5 wt % Fe₃O₄ nanoparticles in the composite of P3HT/PC61BM provided the best efficiency.

Table 2 below shows the performance of the solar cell 10 when Fe₃O₄ nanoparticles were mixed with P3HT:PC61BM and blended in ODCB with a different weight ratio with external magnetic field aligned treatment (The optimal condition is 1.0% (v/v) of Fe₃O₄ nanoparticles in P3HR:PC61BM.).

TABLE 2

| | V_{oc} | | | |
|---|---|---|---|---|
| Fe₃O₄ NPs^{a}/P3HT:PC61BM^{b} | (V) | J_{sc} (mA/cm²) | FF (%) | PCE (%) |
| 0.5 μL/100 μL | 0.60 | 8.40 | 63.4 | 3.20 |
| 1.0 μL/100 μL | 0.60 | 8.97 | 68.3 | 3.67 |
| 2.0 μL/100 μL | 0.57 | 9.18 | 62.8 | 3.28 |
| 5.0 μL/100 μL | 0.55 | 9.10 | 63.7 | 3.19 |
| 20.0 μL/100 μL | 0.45 | 6.65 | 49.0 | 1.47 |

^{a}The concentration of Fe₃O₄ nanoparticles (NPs) is 5 mg/mL on toluene;
^{b}The concentration of P3HT:PC61BM is 10 mg/mL, P3HT:PC61BM = 1:0.8, (w/w).

For example, J_{sc}, for an active aligned active layer 40 formed of P3HT:PC61BM+Fe₃O₄ with magnetically aligned nanochains reached to 8.97 mA/cm², an increase of about 6.9%, as compared with an active layer 40 of P3HT:PC61BM+Fe₃O₄ nanoparticles that were not treated by an external magnetic field-based device (J_{sc}=8.39 mA/cm²). Compared with the pristine P3HT:PC61BM based control solar cells, which achieved a J_{sc}=7.81 mA/cm², the J_{sc} attained an increase of about 14.8%. With the same trends, the J_{sc} of solar cells using PTB7-F20:PC71BM+Fe₃O₄ nanochains treated with magnetic field alignment attained an increase of about 6.1%, as compared with solar cells formed of PTB7-F20:PC71BM+Fe₃O₄ nanoparticles without the magnetic field alignment, and attained an increase of about 15.4%, as compared with solar cells formed of pristine PTB7-F20:PC71BM. Considering that solar cell efficiency is closely related to the BHJ thickness and the performance of the solar cell, it is submitted that the thickness of the three types of active layers considered above (i.e. pristine polymer/fullerene; polymer/fullerene+Fe₃O₄ nanoparticles; and polymer/fullerene+Fe₃O₄ with aligned nanochains) were equal, and therefore, the factor of active layer thickness influencing the efficiency can be excluded. Thus, the Fe₃O₄ nanochains play an important role in the BHJ active layer 40, and provide several operational benefits. Simultaneously, with the enhancement of the short-circuit current density (J_{sc}), the fill factor (FF) of the PTB7-F20:PC71BM+aligned Fe₃O₄ nanochain-based solar cell 10 is found to be 66.4%, which is higher than that of the control devices (63.6% and 65.3%). Furthermore, the same trend was also found in P3HT:PC61BM based solar cells, which suggests that the charge transport properties are substantially improved. In addition, it is observed that a series resistance (Rₛ) reduction enhancement to the solar cell 10 also accompanies the introduction of the aligned Fe₃O₄ nanochains into the solar cell 10. This means that the introduced Fe₃O₄ nanochains contribute to increase the conductivity of the active layer 40 formed of the polymer/fullerene composites of P3HT:PC61BM and PTB7-F20:PC71BM. Thus, the significant reduction in series resistance (Rₛ) values for organic photovoltaic devices (OPV), such as solar cell 10, that are achieved using new materials or fabrication techniques discussed herein, results in increased operational efficiency of the solar cell 10.

The accuracy of the photovoltaic measurements can be confirmed by the external quantum efficiency (EQE) of the solar cells 10. Specifically, the EQE curves of the solar cells 10 fabricated were measured under the same optimized conditions as those used for the J-V measurements. The external quantum efficiency (EQE) values for solar cell 10 having PTB7-F20:PC71BM blended with magnetic field aligned Fe₃O₄ nanochains is shown in FIG. 7A, which are all higher than their control devices, which agree with the higher J_{sc} values of the devices derived from aligned Fe₃O₄ nanochains blended with PTB7-F20:PC71BM. To evaluate the accuracy of the photovoltaic results, the J_{sc} values were calculated by integrating the external quantum efficiency (EQE) data with an AM 1.5G reference spectrum. The J_{sc} values obtained using integration and J-V measurements were close and within 5% error. For example, the calculated J_{sc} value of the solar cell based on aligned Fe₃O₄ nanochains blended with PTB7-F20:PC71BM was 13.25 mA/cm², which is 4.4% lower than the value obtained from the J-V curve (13.86 mA/cm²). Similarly, the calculated J_{sc} value of the device based on pristine PTB7-F20:PC71BM was 11.46 mA/cm², which is 4.6% lower than the value obtained from the J-V curve (12.01 mA/cm²), and for the PTB7-F20:PC71BM+Fe₃O₄ nanoparticles without magnetic field alignment, the error is 3.3%.

The external quantum efficiency (EQE) value for the solar cell containing PTB7-F20:PC71BM+Fe₃O₄ nanochains induced by a magnetic field is higher than those for pristine PTB7-F20:PC71BM and PTB7-F20:PC71BM+Fe₃O₄ nanoparticles in the absence of a magnetic field in mostly wavelength. For example, the solar cells 10 using PTB7-F20:PC71BM+Fe₃O₄ aligned nanochains was found to have an EQE maximum of 60.7% at 620 nm, and the EQE of the hybrid photovoltaic device with PTB7-F20:PC71BM+Fe₃O₄ nanoparticles is 57.9% at the same wavelength. The difference is a consequence of increasing the rate of exciton generation and the probability of exciton dissociation, thereby enhancing J_{sc} density. The EQE results closely matches the values measured from J-V characteristics, which indicate that the photovoltaic results are reliable.

FIG. 7B presents the normalized UV(ultra-violet)-visible spectra of pristine PTB7-F20:PC71BM and PTB7-F20:PC71BM blended with Fe₃O₄ nanoparticles with and without the external magnetic field treatment. The films used for absorption measurements were controlled to be roughly the same thickness. No obvious change in absorption wavelength was observed when the active layer 40 was blended with Fe₃O₄ nanoparticles, but greater optical absorption was found by blending the Fe₃O₄ nanoparticles into the active layer 40. This may be due to the high refractive index of the Fe₃O₄ nanoparticles and nanochains, which results in a high optical absorption in organic hybrid active layer.

It should be appreciated that for a given absorption profile of a given material, the bottleneck is the mobility of charge carriers, and it is one of the major concerns in designing organic photovoltaic materials and in fabricating polymer solar cells (PSC). High charge carrier mobility is preferred for efficient transportation and photocurrent collection of the photo-induced charge carriers. In order to make a realistic evaluation on the apparent charge carrier mobility in the active layer, the electron and hole mobilities of Fe₃O₄ nanoparticle blended polymers (P3HT and PTB7-F20) and fullerenes (PC61BM and PC71BM) based active layers 40 were measured by a space-charge limited current (SCLC) method with the hole-only and electron-only devices. This was done to investigate the effect of the Fe₃O₄ nanoparticles and nanochains on the electron and hole mobility, respectively, and the results are discussed herein.

Specifically, the thickness of the films was measured with atomic force microscopy (AFM). The current-density-voltage (J-V) curves were measured using a Keithley 2400 source measuring unit. The photocurrent was measured under AM 1.5G illumination at 100 mW/cm⁻² under a Newport Thermal Oriel 91192 1000W solar simulator (4 in.×4 in. beam size). The light intensity was determined by a monosilicon detector with a KG-5 visible color filter calibrated by National Renewable Energy Laboratory (NREL) to reduce spectral mismatching. After collecting external quantum efficiency (EQE) data, the AM 1.5G standard spectrum, the Oriel solar simulator (with 1.5G filter) spectrum, and EQE data of both the reference cell and tested polymer solar cells to calculate the spectral mismatch factor in accordance with standard accepted procedures.

The SCLC method was used to test the hole and electron mobility. The dielectric constant εᵣ is assumed to be 3 in the analysis, which is a typical value for conjugated polymers.

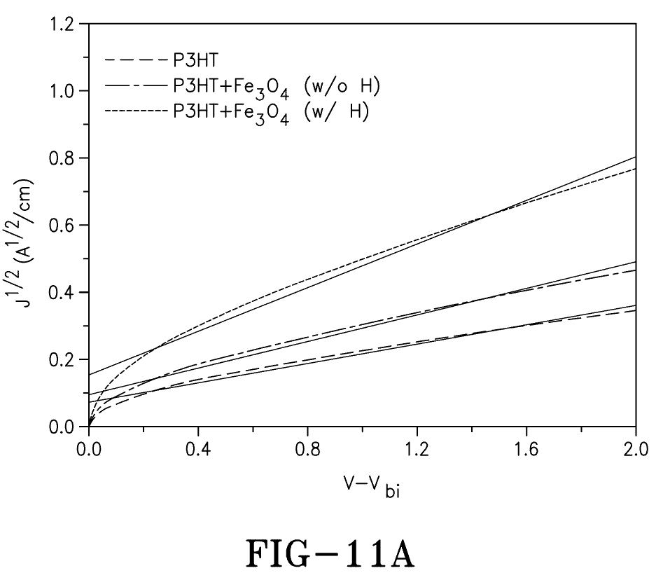

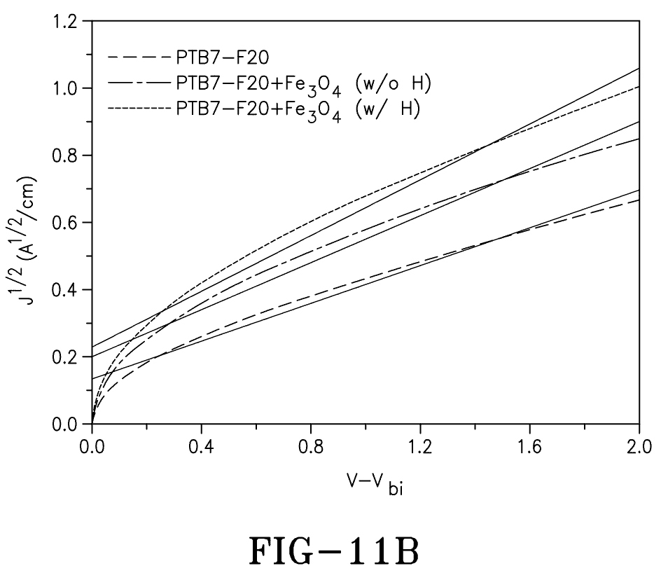

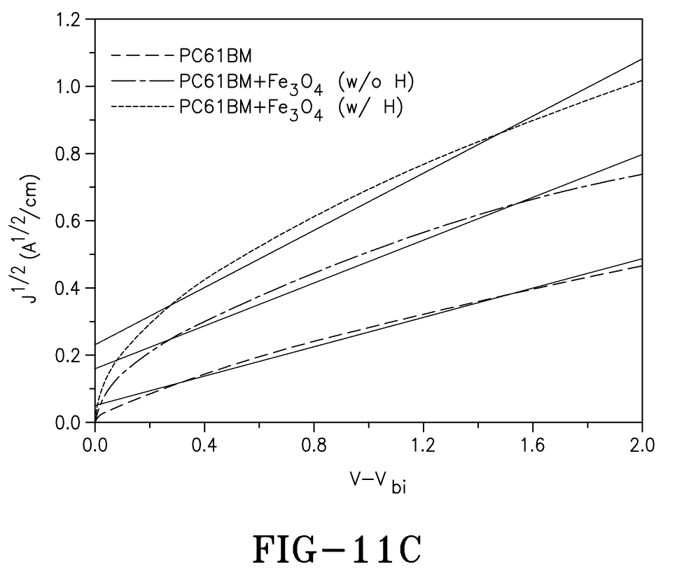

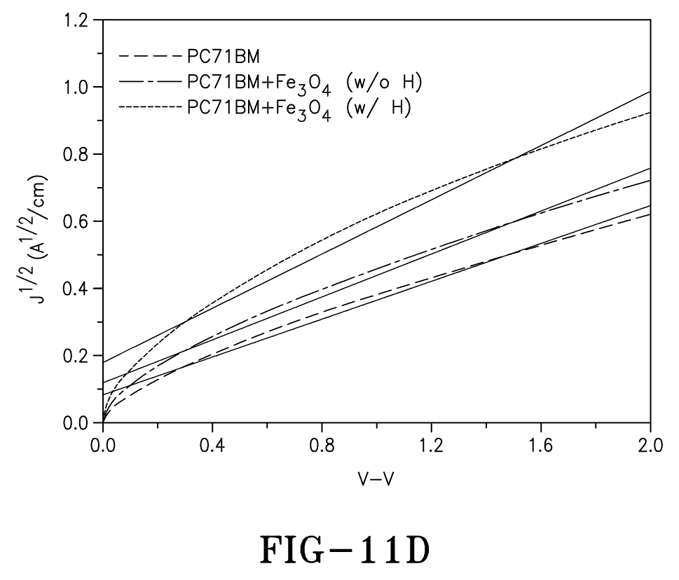

Hole mobility was measured using a diode configuration of ITO/PEDOT:PSS/polymer or polymer+Fe₃O₄/MoO₃/Ca/Al by taking current-voltage current in the range of 0-2 V and fitting the results to a space charge limited form. Specifically, FIGS. 11A-D show the effect of the Fe₃O₄ nanoparticles without and with magnetic field aligned treatment on charge transport properties, whereby the solid line shown in FIGS. 11A-D is the fit of the data points. The J^{1/2}-(V-V_{bi}) curves of the pristine P3HT, P3HT+Fe₃O₄ nanoparticles and pristine PTB7-F20, PTB7-F20+Fe₃O₄ nanoparticles without and with magnetic field treated-based films are shown in FIGS. 11A and 11B.

Electron mobility was measured using a diode configuration of ITO/Ca/Al/polymer or polymer+Fe₃O₄/Ca/Al by taking current-voltage current in the range of 0-2 V. FIG. 11C shows the J^{1/2}-(V-V_{bi}) curves of the pristine PC61BM, Fe₃O₄ nanoparticles blended PC61BM without and with magnetic field aligned films. The structure of electron mobility test for PC71BM is slightly different from the PC61BM based one, about 3 nm thickness of C₇₀ was evaporated on the top of ITO/Ca/Al, and then spin-coating PC71BM based solution, related J^{1/2}-(V-V_{bi}) curves show in FIG. 11D.

As shown in Table 3 below, polymer+Fe₃O₄ nanoparticles with magnetic field aligned treatment-based films obtained higher electron mobility than pristine fullerene and fullerene+Fe₃O₄ nanoparticles without magnetic field treatment-based films. With the same trend, fullerene+Fe₃O₄ nanochain based films obtained higher electron mobility than pristine fullerene and fullerene+Fe₃O₄ nanoparticles based films. These results are good and included higher J_{sc} value and lower Rₛ of the polymer solar cell 10 with P3HT:PC61BM and PTB7-F20:PC71BM+Fe₃O₄ nanochain based devices.

TABLE 3

| | | | Electron-only | | |
|---|---|---|---|---|---|
| Hole-only | Thickness | Mobility | mobility | Thickness | Mobility |
| mobility | (nm) | (cm²/Vs) | (cm²/Vs) | (nm) | (cm²/Vs) |
| P3HT | 155 | 1.79 × 10⁻⁵ | PC61BM | 100 | 6.57 × 10⁻⁶ |
| P3HT + Fe₃O₄ | 155 | 2.44 × 10⁻⁵ | PC61BM + Fe₃O₄ | 100 | 1.34 × 10⁻⁵ |
| (w/o H) | | | (w/o H) | | |
| P3HT + Fe₃O₄ | 155 | 4.01 × 10⁻⁵ | PC61BM + Fe₃O₄ | 100 | 2.39 × 10⁻⁵ |
| (w/H) | | | (w/H) | | |
| PTB7-F20 | 180 | 1.53 × 10⁻⁵ | PC71BM | 90 | 7.67 × 10⁻⁶ |
| PTB7- | 180 | 2.37 × 10⁻⁵ | PC71BM + Fe₃O₄ | 90 | 9.93 × 10⁻⁶ |
| F20 + Fe₃O₄ | | | (w/o H) | | |
| (w/o H) | | | | | |
| PTB7- | 180 | 3.33 × 10⁻⁵ | PC71BM + Fe₃O₄ | 90 | 1.58 × 10⁻⁵ |
| F20 + Fe₃O₄ | | | (w/H) | | |
| (w/H) | | | | | |

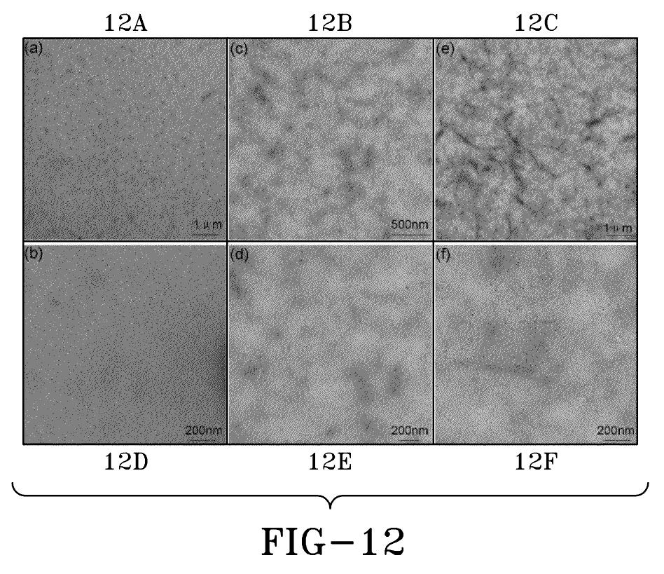

FIGS. 12A-F show TEM images of pristine P3HT:PC61BM (FIGS. 12A-B), P3HT:PC61BM+Fe₃O₄ nanoparticles without magnetic field alignment (FIGS. 12C-D), and P3HT:PC61BM+Fe₃O₄ nanochains with magnetic field alignment (FIGS. 12E-F) are shown in FIG. 12. The morphology of BHJ film processed with Fe₃O₄ nanochains aligned by magnetic field showed larger scale phase separation than that in the BHJ film without field aligned and added nanoparticles.

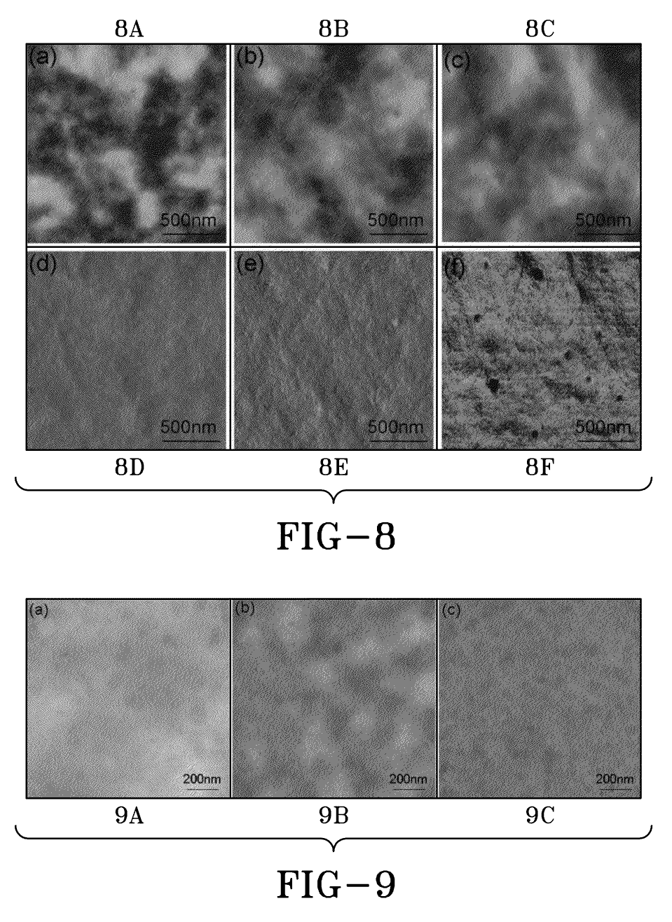

Moreover, for the electron or hole-only solar cells space-charge limited current (SCLC) is described by:

$$J = \frac{8}{9} {ɛ}_{r} {ɛ}_{0} μ \frac{{V}^{2}}{{L}^{3}} \qquad ( 8 )$$

where J is the current density, εᵣ is the dielectric constant of the polymer and fullerene derivatives, respectively, ε₀ is the permittivity of a vacuum, L is the thickness of the blended film or active layer 40, V=Vₐₚₚₗ−V_{bi}, Vₐₚₚₗ is the applied potential, and V_{bi} is the built-in potential which results from the difference in the work function of the anode and the cathode (in these device structures, V_{bi}=0 V). FIG. 8 shows that the polymers P3HT and PTB7-F20 with aligned Fe₃O₄ nanochains exhibited higher hole mobilities than the polymer/Fe₃O₄ nanoparticles without external magnetic field alignment and pristine polymer-based control devices. With the same trend, the solar cells using polymers PC61BM and PC71BM with aligned Fe₃O₄ nanochains exhibited higher electron mobilities than their related control devices (e.g. 40 devices show the same trend). The active layer mobility enhancement and the series resistance (Rₛ) reduction produced by the Fe₃O₄ nanoparticles and external magnetic field are consistent with expected results. FIG. 8 also shows the surface topography measured by atomic force microscopy (AFM) of films cast from pristine P3HT:PC61BM (FIGS. 8A-B), P3HT:PC61BM without magnetic field induced aligned Fe₃O₄ nanoparticles (FIGS. 8C-D), and P3HT:PC61BM with blended magnetic field induced aligned Fe₃O₄ nanochains (FIGS. 8E-F), respectively. The morphology of the film processed with magnetic field induced aligned Fe₃O₄ nanochains showed more elongated domains than the pristine P3HT:PC61BM. The aligned Fe₃O₄ blended film showed large scale phase separation with rod-like shape domains and bicontinuous networks.

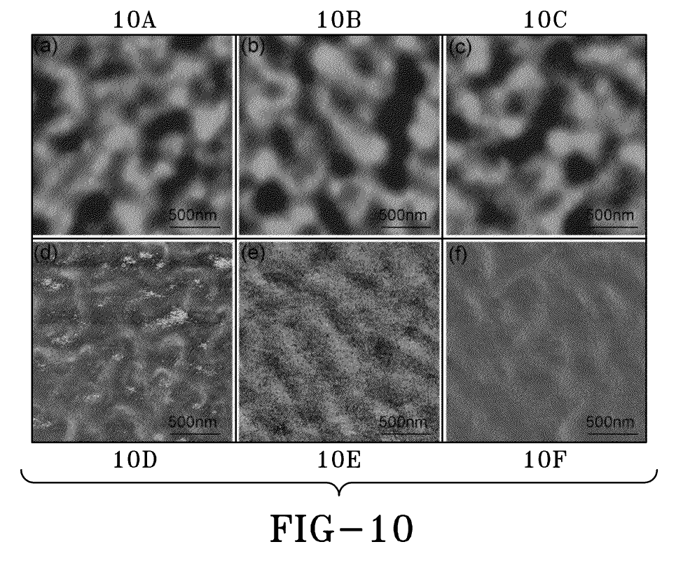

Charge carrier mobility is not a parameter of a material, but a device parameter, and it is sensitive to the nanoscale morphology of the thin film of the photoactive layer. In a van der Waals crystal for example, the final nano-morphology depends on film preparation. Parameters such as solvent type, solvent evaporation (crystallization) time, temperature of the substrate, and/or deposition method can change the nano-morphology. In the present invention, although the processing conditions (e.g. solvent, concentration, spin-coating parameters, etc.) of the magnetic field aligned Fe₃O₄ nanoparticles blended polymer/fullerene (P3HT:PC61BM and PTB7-F20:PC71BM) devices are similar to those used for the fabrication of the control devices, (i.e. pristine polymer/fullerene device and Fe₃O₄ nanoparticles blended polymer/fullerene device without the magnetic field alignment treatment), differences were apparent in the nano-morphology and phase separation among the thin films of the pristine polymer/fullerene, the polymer/fullerene+Fe₃O₄ nanoparticles without and with magnetic field alignment treatment, as confirmed by the transmission electron microscopy (TEM) and atomic force microscopy (AFM) measurements, shown in FIGS. 9 and 10.

Specifically, FIG. 9 shows TEM images of the pristine PTB7-F20:PC71BM film (FIG. 9A), PTB7-F20:PC71BM+Fe₃O₄ nanoparticles without external magnetic field alignment treatment (FIG. 9B), and PTB7-F20:PC71BM+Fe₃O₄ nanochains aligned by an external magnetic field (FIG. 9C). Without any treatment, such as the thermal annealing, the interpenetrating networks of pristine PTB7-F20:PC71BM film, as shown in FIG. 9A, and Fe₃O₄ nanoparticles blended film without a magnetic field, as shown in FIG. 9B, are not well developed, and the D-A domains are difficult to distinguish. For Fe₃O₄ nanochains blended films after magnetic field alignment treatment, as shown in FIG. 9C, the morphology of the interpenetrating D-A networks becomes clearer and easily visible. The changes in morphology result in a large interfacial area for efficient charge generation.

The morphology of polymer/fullerene BHJ films influenced by Fe₃O₄ nanoparticles and an external magnetic field were investigated using atomic force microscopy (AFM). FIGS. 10A-B show the surface topography and phase images of a pristine PTB7-F20:PC71BM based film, while the surface topography and phase images of PTB7-F20:PC71BM+Fe₃O₄ nanoparticles without an external magnetic field treatment are shown in FIGS. 6C-D, and with an external magnetic field treatment are shown in FIGS. 6E-F, respectively. The phase separation for all the blend films is shown with bright islands for the PTB7-F20 polymer and dark valleys for the PC71BM fullerene derivatives. There are large fullerene derivative aggregates being confined within the PTB7-F20 matrix, which implies that an interpenetrating network was formed in the blended films, which is beneficial for forming an efficient exciton dissociation interface and bicontinuous charge transport channels. The surface RMS (root-mean-square) roughness of films formed from pristine PTB7-F20:PC71BM, from PTB7-F20:PC71BM+Fe₃O₄ nanoparticles without magnetic field alignment treatment, and from PTB7-F20:PC71BM+Fe₃O₄ nanochains aligned by magnetic field are 10.7, 12.2, and 11.4 nm, respectively. The surface RMS for each film is not too rough to lower the photovoltaic performance of the solar cell 10.

Thus, the solar cell 10 utilizes the spin polarization effect of magnetic nanostructures, which is implemented by the alignment of Fe₃O₄ nanoparticles (NPs) to form nanochains (NCs) upon exposure to an external magnetic field through dipolar-dipolar interactions between nanoparticles. The paramagnetism of the aligned Fe₃O₄ nanochains produce an internal electrical field through spin-polarization, which both increase the charge separation efficiency of the solar cell 10 and ensure high mobility charge carrier transport in the active layer 40 of the BHJ based solar cell 10. Furthermore, the solar cell 10 utilizes two types of polymer/fullerene systems, P3HT:PC61BM and PTB7-F20:PC71BM blended with Fe₃O₄ nanoparticles, which after being introduced to an external magnetic field, form Fe₃O₄ nanochains. As a result, the photon conversion efficiency (PCE) achieved by solar cell 10 increased by 14.8% and 15.4%, as compared with their pristine polymer/fullerene based devices, respectively. The enhanced photon conversion efficiency was mainly the result of the increased short-circuit current density (J_{sc}).

Therefore, one advantage of the present invention is that a polymer solar cell (PSC) is manufactured using simple solution processing, so as to increase its conversion efficiency. Another advantage of the present invention is that a polymer solar cell increases the short circuit current density (J_{sc}) therein. Still another advantage of the present invention is that a polymer solar cell increases the short circuit current density (J_{sc}) by adjusting the morphology and phase separation of the polymer/fullerene based active layers. Yet another advantage of the present invention is that an internal electric field induced by spin-polarization of the aligned Fe₃O₄ nanochains of a solar cell increases the charge separation and charge transport processes of the solar cell, and thus enhances the short circuit current density (J_{sc}). Still another advantage of the present invention is that a polymer solar cell includes an active layer that is formed of a solution-processed composite material, whereby the solution process includes spin-casting, dip-casting, drop-casting, as well as any printing technology, such as spray-coating, dip-coating, doctor-blade coating, slot coating, dispensing, ink-jet printing, thermal transfer printing, silk-screen printing, offset printing, gravure printing, and flexo printing. Yet another advantage of the present invention is that a polymer solar cell using an active layer with aligned Fe₃O₄ nanochains has a reduced series resistance (Rₛ), allowing the solar cell to have increased efficiency.

Thus, it can be seen that the objects of the invention have been satisfied by the structure and its method for use presented above. While in accordance with the Patent Statutes, only the best mode and preferred embodiment has been presented and described in detail, it is to be understood that the invention is not limited thereto or thereby. Accordingly, for an appreciation of the true scope and breadth of the invention, reference should be made to the following claims.

What is claimed is:

1. A solar cell comprising:
an at least partially light transparent electrode;
an active layer disposed upon said at least partially transparent, said active layer formed of a composite of at least one conjugated polymer as an electron donor, at least one fullerene as an electron acceptor, and Fe₃O₄ nanochains formed of Fe₃O₄ nanoparticles aligned along their magnetic dipole moments; and
a second electrode disposed upon said active layer.

2. The solar cell of claim 1, wherein said plurality of Fe₃O₄ nanochains are linear.

3. The solar cell of claim 2, wherein said Fe₃O₄ nanochains are induced from said nanoparticles upon the application of an external magnetic field.

4. The solar cell of claim 1, wherein said at least one conjugated polymer is selected from the group consisting of poly(3-hexylthiophene) (P3HT), and thieno[3,4-b]thiophene benzodithiophene (PT7-F20).

5. The solar cell of claim 1, wherein said at least one fullerene is selected from the group consisting of thieno[3,4-b]thiophene benzodithiophene (PC61BM), and phenyl-c71-butyric acid methyl ester (PC71BM).

6. The solar cell of claim 1, wherein said at least partially light transparent electrode comprises indium-tin-oxide (ITO).

7. The solar cell of claim 1, wherein said second electrode comprises a composite of calcium and aluminum.

8. A method of forming a solar cell comprising:
providing an at least partially light transparent electrode;
providing a mixture of at least one polymer as an electron donor, at least one fullerene as an electron acceptor, and Fe₃O₄ nanoparticles;
disposing said mixture upon said at least partially light transparent electrode to form an active layer;
exposing said mixture to a magnetic field, such that Fe₃O₄ nanochains are formed from said Fe₃O₄ nanoparticles, and are aligned along their magnetic dipole moments; and
disposing a second electrode upon said active layer.

9. The method of claim 8, wherein said plurality of Fe₃O₄ nanochains are linear.

10. The method of claim 9, wherein said Fe₃O₄ nanochains are induced from said nanoparticles upon the application of an external magnetic field.

11. The method of claim 8, wherein said at least one polymer is selected from the group consisting of poly(3-hexylthiophene) (P3HT), and thieno[3,4-b]thiophene benzodithiophene (PTB7-F20).

12. The method of claim 8, wherein said at least one fullerene is selected from the group consisting of thieno[3,4-b]thiophene benzodithiophene (PC61BM), and phenyl-c71-butyric acid methyl ester (PC71BM).

13. The method of claim 8, wherein said at least partially transparent electrode comprises indium-tin-oxide (ITO).

14. The method of claim 8, wherein said second electrode comprises a composite of calcium and aluminum.

15. A solar cell comprising:
an at least partially light transparent electrode;
an active layer disposed upon said at least partially transparent electrode, said active layer formed of a composite of at least one electron donor, at least one electron acceptor, and magnetic nanoparticles aligned along their magnetic dipole moments; and
a second electrode disposed upon said active layer.

16. The solar cell of claim 15, wherein said plurality of magnetic nanoparticles are linear.

17. The solar cell of claim 16, wherein said magnetic nanoparticles are induced from said nanoparticles upon the application of an external magnetic field.

18. The solar cell of claim 16, wherein said the magnetic nanoparticles is a metal oxide or metals, selected from the group consisting of Fe₃O₄, CoO, NiO, Co, and Ni.

19. The solar cell of claim 15, wherein said the electron donor is a conjugated polymer selected from the group consisting of poly(3-hexylthiophene), and thieno[3,4-b]thiophene benzodithiophene.

20. The solar cell of claim 15, wherein said the electron acceptor is a fullerene or fullerene dervitaive selected from the group consisting of thieno[3,4-b]thiophene benzodithiophene, and phenyl-c71-butyric acid methyl ester.

21. The solar cell of claim 15, wherein said at least partially light transparent electrode comprises indium-tin-oxide (ITO) or high work-function metal.

22. The solar cell of claim 15, wherein said second electrode comprises a composite of low work-function metal.

23. A method of forming a solar cell comprising:
providing an at least partially light transparent electrode;
providing a mixture of at least one polymer, at least one fullerene, and magnetic nanoparticles;
disposing said mixture upon said at least partially light transparent substrate to form an active layer;
exposing said mixture to a magnetic field, such that said magnetic nanoparticles are aligned along their magnetic dipole moments; and
disposing a second electrode upon said active layer.

24. The method of claim 23, wherein said magnetic nanoparticles are linear.

25. The method of claim 24, wherein said magnetic nanoparticles are induced from said nanoparticles upon the application of an external magnetic field.

26. The method of claim 23, wherein said at least one polymer comprises p-type organic molecules.

27. The method of claim 23, wherein said at least one fullerene comprises n-type organic molecules.

28. The method of claim 23, wherein said at least partially light transparent electrode comprises indium-tin-oxide (ITO) or a high work-function metal.

29. The method of claim 23, wherein said second electrode comprises a low-work function metal.
